(19) United States
(12) Patent Application Publication
(10) Pub. No.: US 2025/0062172 A1
(43) Pub. Date: Feb. 20, 2025

(54) SEMICONDUCTOR PACKAGE

(71) Applicant: Samsung Electronics Co., Ltd., Suwon-si (KR)

(72) Inventor: Jongbo Shim, Suwon-si (KR)

(21) Appl. No.: 18/782,267

(22) Filed: Jul. 24, 2024

(30) Foreign Application Priority Data
Aug. 17, 2023 (KR) 10-2023-0107920

(51) Int. Cl. H01L 23/31; H01L 23/00; H01L 23/538; H01L 25/10; H10B 80/00

(52) U.S. Cl. CPC H01L 23/3107; H01L 24/16; H01L 24/32; H01L 24/73; H01L 25/105; H01L 23/5383; H01L 2224/16227; H01L 2224/26175; H01L 2224/32225; H01L 2224/73204; H10B 80/00

(57) ABSTRACT

A semiconductor package includes a package substrate, a first semiconductor device on the package substrate, a second semiconductor device on the package substrate and spaced laterally from the first semiconductor device, and a package encapsulant including a first encapsulant and a second encapsulant. The first encapsulant is on the package substrate, is in contact with side surfaces of the first semiconductor device, and encloses the side surfaces of the first semiconductor device. The second encapsulant is on the package substrate and laterally spaced apart from some side surfaces of the second semiconductor device, wherein the first encapsulant and the second encapsulant are integrally provided, and some side surfaces of the package encapsulant are coplanar with an outer edge of the package substrate.

### CROSS-REFERENCE TO RELATED APPLICATION(S)

This application is based on and claims priority under 35 U.S.C. § 119 to Korean Patent Application No. 10-2023-0107920, filed on Aug. 17, 2023, in the Korean Intellectual Property Office, the disclosure of which is incorporated by reference herein in its entirety.

### BACKGROUND

The inventive concept relates generally to a semiconductor package, and more particularly, to a semiconductor package including an encapsulant.

While the storage capacity of a semiconductor chip is of high importance, it is also required that a semiconductor package including the semiconductor chip should become thinner and lighter. In addition, research is being conducted to secure sufficient productivity and reliability of semiconductor packages while manufacturing semiconductor packages including semiconductor chips with various functions therein.

### SUMMARY

The inventive concept, as manifested in one or more embodiments, provides a semiconductor package having improved reliability.

An objective to which the inventive concept is directed is not limited to the above-mentioned objective, and other objectives not explicitly mentioned herein may be clearly understood by those of ordinary skill in the art from the following description.

According to an aspect of the inventive concept, there is provided a semiconductor package including a package substrate, a first semiconductor device mounted on the package substrate, a second semiconductor device mounted on the package substrate and spaced laterally from the first semiconductor device, and a package encapsulant including a first encapsulant and a second encapsulant, wherein the first encapsulant is arranged on the package substrate, in contact with side surfaces of the first semiconductor device and encloses the side surfaces of the first semiconductor device, and the second encapsulant is arranged on the package substrate, and laterally spaced apart from some of side surfaces of the second semiconductor device, wherein the first encapsulant and the second encapsulant are integrally provided, and some of side surfaces of the package encapsulant are coplanar with an outer edge of the package substrate.

In addition, according to another aspect of the inventive concept, there is provided a semiconductor package including a package substrate having a plurality of upper connection pads on a top surface thereof, a first semiconductor device on the package substrate and electrically connected to some of the plurality of upper connection pads, and a package encapsulant including a first encapsulant and a second encapsulant, wherein the first encapsulant is arranged on the package substrate and is in contact with at least some side surfaces of the first semiconductor device at a perimeter of the first semiconductor device, and the second encapsulant is arranged on the package substrate and laterally spaced from the remainder of the plurality of upper connection pads, and encloses outer side surfaces of the remainder of the plurality of upper connection pads, wherein the first encapsulant and the second encapsulant are integrally provided, and a first height, which is a vertical level of the first encapsulant from the top surface of the package substrate, is greater than a second height, which is a vertical level of the second encapsulant, from the top surface of the package substrate, the first height is equal to or greater than a third height, which is a vertical level of a top surface of the first semiconductor device, from the top surface of the package substrate, the first encapsulant and the second encapsulant are integrally provided, and some side surfaces of the package encapsulant are coplanar with an outer edge of the package substrate.

In addition, according to another aspect of the inventive concept, there is provided a semiconductor package including a package substrate having a plurality of upper connection pads on a top surface thereof, a first semiconductor device on the package substrate and electrically connected to some of the plurality of upper connection pads, and a package encapsulant including a first encapsulant and a second encapsulant, wherein the first encapsulant is arranged on the package substrate and in contact with at least some side surfaces of the first semiconductor device at a perimeter of the first semiconductor device, and the second encapsulant is arranged on the package substrate and laterally spaced from the remainder of the plurality of upper connection pads, and encloses outer side surfaces of the remainder of the plurality of upper connection pads, wherein the first encapsulant and the second encapsulant are integrally provided, and a first height, which is a vertical level of the first encapsulant from the top surface of the package substrate, is greater than a second height, which is a vertical level of the second encapsulant, from the top surface of the package substrate, the second height is less than or equal to half the first height, the first height is equal to or greater than a third height, which is a vertical level of a top surface of the first semiconductor device from the top surface of the package substrate, the first encapsulant and the second encapsulant are integrally provided, and some side surfaces of the package encapsulant are coplanar with an outer edge of the package substrate.

### BRIEF DESCRIPTION OF THE DRAWINGS

Embodiments of the inventive concept will be more clearly understood from the following detailed description taken in conjunction with the accompanying drawings, wherein like reference numerals (when used) indicate corresponding elements throughout the several views, and in which:

FIG. 1 is a plan view of an example semiconductor package according to an embodiment of the present disclosure;

FIG. 2 is a cross-sectional view illustrating the example semiconductor package of FIG. 1 according to an embodiment, taken along line I-I′;

FIG. 3 is a plan view of an example semiconductor package according to an embodiment of the present disclosure;

FIG. 4 is a cross-sectional view illustrating the example semiconductor package of FIG. 3 according to an embodiment, taken along line II-II′;

FIG. 5A is an enlarged cross-sectional view of a portion A of the semiconductor package shown in FIG. 3, according to an embodiment;

FIG. 5B is an enlarged cross-sectional view of a portion A of the semiconductor package shown in FIG. 3, according to an embodiment;

FIG. 6 is a cross-sectional view illustrating an example semiconductor package according to an embodiment of the present disclosure;

FIGS. 7 to 10 are plan view diagrams depicting intermediate processes in an example method of manufacturing a semiconductor package, according to one or more embodiments of the present disclosure;

FIG. 11 is a plan view of a semiconductor package according to an embodiment of the present disclosure; and

FIG. 12 is a plan view of a semiconductor package according to an embodiment of the present disclosure.

### DETAILED DESCRIPTION

Hereinafter, embodiments of the technical idea of the inventive concept will be described in detail with reference to the accompanying drawings. The same reference numerals are used for the same components in the drawings, and redundant descriptions thereof will be omitted.

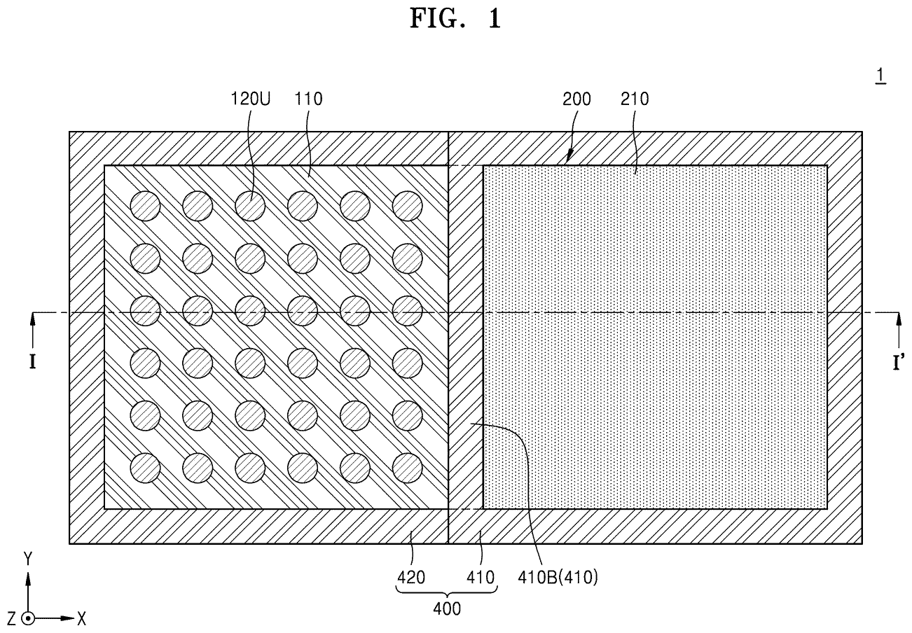

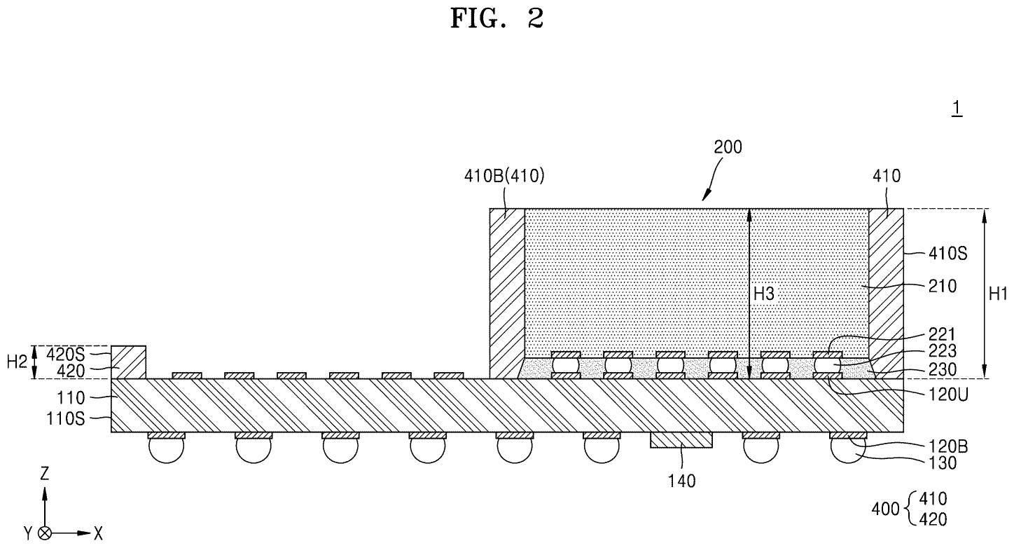

FIG. 1 is a plan view of an example semiconductor package 1, according to an embodiment of the present disclosure. FIG. 2 is a cross-sectional view illustrating the example semiconductor package 1 of FIG. 1 according to an embodiment taken along line I-I′.

Referring to FIGS. 1 and 2, the semiconductor package 1 according to an embodiment may include a package substrate 110, a first semiconductor device 200 on the package substrate 110, and a package encapsulant 400 on the package substrate 110.

In the present specification, a horizontal plane means an X-Y plane parallel to an upper surface of the package substrate 110, a first horizontal direction means an X direction, and a second horizontal direction means a Y direction, the X direction intersecting the Y direction. A vertical direction refers to a direction perpendicular to an X-Y plane, and the vertical direction refers to a Z direction perpendicular to the upper surface of the package substrate 110. The vertical direction may be perpendicular to the first horizontal direction, and at the same time, the vertical direction may be perpendicular to the second horizontal direction.

The package substrate 110 may be a printed circuit board (PCB) including wiring therein. A plurality of lower connection pads 120B may be on a bottom surface of the package substrate 110, and an external connection terminal 130 may be provided on each of the lower connection pads 120B. A plurality of upper connection pads 120U may be provided on a top surface of the package substrate 110. A passive device 140 may be provided on the bottom surface of the package substrate 110. The passive device 140 may include, for example, a capacitor, an inductor, and/or a resistor. As used herein, the term “and/or” includes any and all combinations of one or more of the associated listed items. The passive device 140 may be electrically connected to other components. The term “connected” (or “connecting,” “contact,” “contacting,” or like terms), as may be used herein, is intended to broadly refer to a physical and/or electrical connection between two or more elements, and may include other intervening elements unless the context indicates otherwise.

The first semiconductor device 200 may be provided (e.g., mounted, attached or otherwise arranged) on the top surface of the package substrate 110. The first semiconductor device 200 may include a first semiconductor substrate 210, first connection pads 221, and first connection terminals 223.

The first semiconductor device 200 may include a first semiconductor substrate 210 having an active surface, and a plurality of first chip connection pads 221 arranged on the active surface of the first semiconductor substrate 210. The first semiconductor device 200 may be a semiconductor chip.

The first semiconductor substrate 210 may include, for example, a semiconductor material such as silicon (Si). Alternatively, the first semiconductor substrate 210 may include semiconductor elements, such as germanium (Ge), or compound semiconductors, such as silicon carbide (SiC), gallium arsenide (GaAs), indium arsenide (InAs), and/or indium phosphide (InP). The first semiconductor substrate 210 may include a conductive region, for example, a well doped with impurities. The first semiconductor substrate 210 may have various device isolation structures such as, for example, a shallow trench isolation (STI) structure.

A semiconductor device including a plurality of various types of individual devices may be formed on the active surface of the first semiconductor substrate 210. The plurality of individual devices may include image sensors such as various microelectronic devices, such as metal-oxide-semiconductor field effect transistors (MOSFETs) such as complementary metal-insulator-semiconductor (CMOS) transistors, system large scale integration (LSI), and CMOS imaging sensors (CIS), micro-electro-mechanical systems (MEMS), active devices, passive devices, etc.

The plurality of individual devices may be electrically connected to the conductive region of the first semiconductor substrate 210. The semiconductor device may further include a conductive wire or a conductive plug electrically connecting at least two of the plurality of individual devices, or the plurality of individual devices to the conductive region of the first semiconductor substrate 210. In addition, each of the plurality of individual devices may be electrically separated from other neighboring individual devices by an insulating film.

For example, the first semiconductor device 200 may include an application processor (AP) such as a central processing unit (CPU), a graphic processing unit (GPU), a field-programmable gate array (FPGA), a digital signal processor, an encryption processor, a microprocessor, and a microcontroller. For example, the first semiconductor device 200 may be a logic chip such as an analog-to digital converter (ADC) or an application-specific integrated circuit (ASIC), or may include a memory chip such as a volatile memory (e.g., a dynamic random-access memory (DRAM)) or a nonvolatile memory (e.g., read-only memory (ROM) or flash memory). The first semiconductor device 200 may be a system-on-chip (SOC). In addition, the first semiconductor device 200 may be configured by a combination of the logic chip, the memory chip, and/or the SOC, which may be combined with one another.

In some embodiments, the first semiconductor device 200 may be provided on the package substrate 110 by a flip-chip bonding method. For example, the first connection terminals 223 may be provided between some of the upper connection pads 120U on the top surface of the package substrate 110 and the first chip pad 221 on the bottom surface of the first semiconductor device 200. The first connection terminals 223 may electrically connect the package substrate 110 with the first semiconductor device 200. For example, the first connection terminals 233 may be solder balls or microbumps, although embodiments are not limited thereto.

The semiconductor package 1 according to an embodiment may include a first underfill layer 230. The first underfill layer 230 may fill a space between the first semiconductor device 200 and the package substrate 110 and may surround the first connection terminals 233. The term “fill” (or “filling,” “filled,” or like terms), as may be used herein, is intended to refer broadly to either completely filling a defined space (e.g., a space surrounding the first connection terminals 233) or partially filling the defined space; that is, the defined space need not be entirely filled but may, for example, be partially filled or have voids or other spaces throughout. The first underfill layer 230 may include a resin, in some embodiments. For example, the first underfill layer 230 may be formed of an epoxy resin by a capillary underfill method. A filler may be mixed in the first underfill layer 230, and the filler may be formed of, for example, silica.

The first underfill layer 230 may be provided between the first semiconductor device 200 and the package substrate 110 before the package encapsulant 400 to be described later is formed on the package substrate 110. Since the first underfill layer 230 is formed before forming the package encapsulant 400, the first underfill layer 230 may be surrounded by the package encapsulant 400, and the package encapsulant 400, in particular, the first encapsulant 410, may be formed in a shape complementary to the shape of the first underfill layer 230. The term “surrounded” (or “surround” or like terms, such as “enclose”), as may be used herein, is intended to broadly refer to an element, structure or layer that extends around, envelops, encircles, or encloses another element, structure or layer on all sides, although breaks or gaps may also be present.

As the first underfill layer 230 is formed, an area of a planar shape of the bottom surface of the first underfill layer 230 in contact with the top surface of the package substrate 110 may be larger than an area of a planar shape of the top surface of the first underfill layer 230 in contact with the bottom surface of the first semiconductor device 200. In other words, the shape of the cross-section of the first underfill layer 230 as shown in FIG. 2 may have a shape in which the width of the horizontal plane narrows as the vertical distance from the package substrate 110 increases. For example, the shape of the cross-section of the first underfill layer 230 may form a rough tapered shape in which the horizontal width decreases as the vertical distance from the package substrate 110 increases. In the shape of the first encapsulant 410 surrounding (i.e., extending around) the first underfill layer 230, as the distance from the package substrate 110 increases, the horizontal distance between the inner surfaces of the first encapsulants 410 facing each other with the first underfill layer 230 between them may become closer. A portion of the first encapsulant 410 in contact with the first underfill layer 230 may not be perpendicular to the top surface of the package substrate 110. Alternatively, a surface opposite to a surface facing the first semiconductor device 200 may be perpendicular to the top surface of the package substrate 110.

The semiconductor package 1 according to an embodiment may include a package encapsulant 400. The package encapsulant 400 may include a first encapsulant 410 and a second encapsulant 420. The first encapsulant 410 and the second encapsulant 420 may be integrally formed. The term “integrally formed” as used herein is intended to refer broadly to two or more components or elements that are connected together so as to make up a single complete piece or unit. A part of the first encapsulant 410 may be an intermediate encapsulant 410B. The first encapsulant 410 may be positioned on the package substrate 110 to surround the side surfaces of the first semiconductor device 200. That is, the first encapsulant 410 may be configured on the package substrate 110 to be in contact with the side surfaces of the first semiconductor device 200.

Like the first encapsulant 410, the intermediate encapsulant 410B may be in contact with the side surface of the first semiconductor device 200. However, as shown in FIGS. 1 and 2, the opposite surface of the surface of the intermediate encapsulant 410B in contact with the first semiconductor device 200 may face the top surface of the package substrate 110 from which some of the upper connection pads 120U are exposed. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

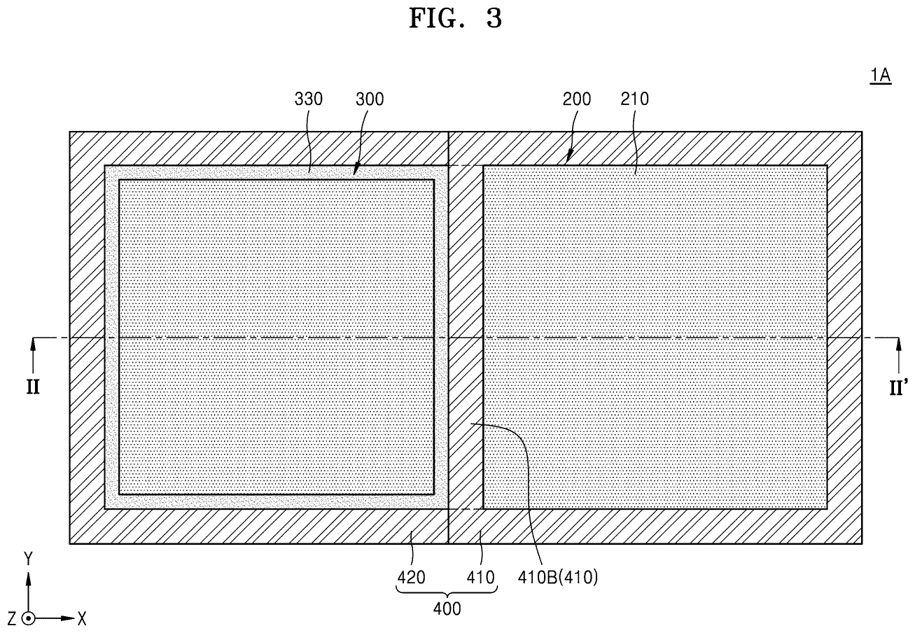

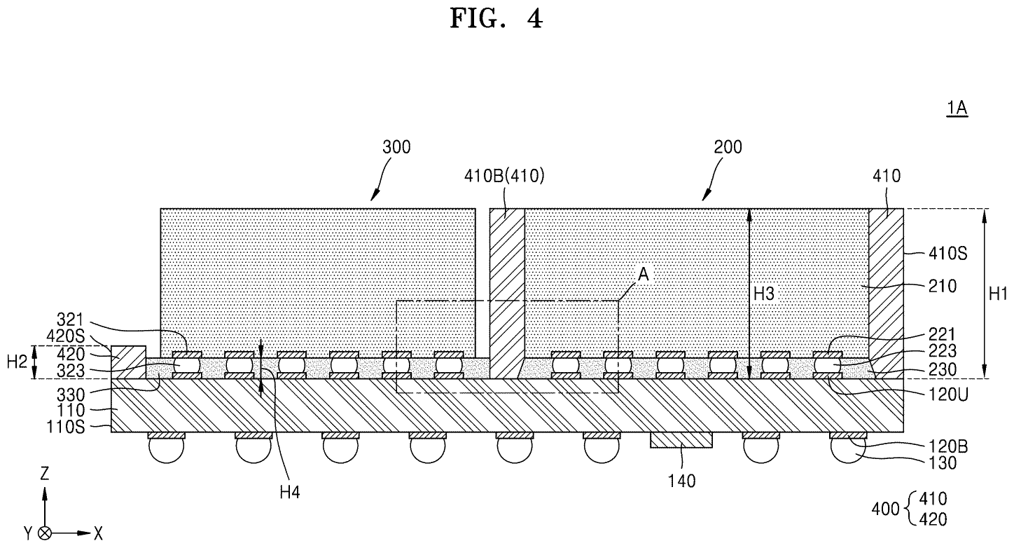

The second encapsulant 420 may be provided on the package substrate 110 in a shape of emptying a space in which a second semiconductor device 300, which will be described later with reference to FIGS. 3 and 4, may be provided on the package substrate 110. That is, the second encapsulant 420 may be on the package substrate 110 at a position spaced apart horizontally from the first semiconductor device 200 and facing a surface opposite to a surface of the intermediate encapsulant 410B in contact with the first semiconductor device 200.

Some of a plurality of upper connection pads 120U to be connected to the second semiconductor device 300 may be positioned inside the second encapsulant 420 so that the second semiconductor device 300, which will be described later in connection with FIGS. 3 and 4, may be connected to some of the plurality of upper connection pads 120U provided on the package substrate 110. Alternatively, the plurality of upper connection pads 120U may be provided between the opposite inner surfaces of the second encapsulant 420, and a part of the top surface of the package substrate 110 may be exposed. In other words, some (i.e., a first subset) of the plurality of upper connection pads 120U may be connected to the first semiconductor device 200, and the rest (i.e., a second subset) of the plurality of upper connection pads 120U may be provided inside the second encapsulant 420. That is, the rest of the plurality of upper connection pads 120U may be laterally (i.e., horizontally) spaced apart from the second encapsulant 420 and the outer surfaces of the rest of the plurality of upper connection pads 120U may be surrounded by the second encapsulant 420. When the second semiconductor device 300 is mounted on the package substrate 110, the second semiconductor device 300 may be electrically connected to the rest of the plurality of upper connection pads 120U.

For example, when the planar shape of the second semiconductor device 300 is rectangular, the shape formed by the inside of the second encapsulant 420 may have a shape similar to the rectangular shape that is the planar shape of the second semiconductor device 300. However, for smooth mounting of the second semiconductor device 300 on the package substrate 110, the planar shape of the second semiconductor device 300 may be included in the shape made by the inside of the second encapsulant 420. As will be described later, when the second semiconductor device 300 is mounted on the package substrate 110, the side surface of the second semiconductor device 300 and the second encapsulant 420 may be spaced apart from each other.

A first height H1, which is a vertical level of the top surface of the first encapsulant 410 with respect to the top surface of the package substrate 110, may be greater than a second height H2, which is a vertical level of the top surface of the second encapsulant 420 with respect to the top surface of the package substrate 110. In an embodiment, the second height H2 may be less than or equal to half the first height H1. The first height H1 may be greater than or the same as a third height H3, which is a vertical level of the top surface of the first semiconductor device 200 with respect to the top surface of the package substrate 110. In the present specification, it will be understood that the meaning of being the same is disclosed in consideration of errors that may occur in the process.

In other words, when the vertical level of the top surface of the first semiconductor device 200 with respect to the top surface of the package substrate 110 is the same as the first height H1, the top surface of the first encapsulant 410 and the top surface of the first semiconductor device 200 may be coplanar. Alternatively, the first encapsulant 410 may cover a top surface of the first semiconductor device 200. That is, the first height H1 may be greater than a vertical level of the top surface of the first semiconductor device 200 with respect to the top surface of the package substrate 110.

The package encapsulant 400 may serve to protect the first semiconductor device 200 from external (i.e., environmental) effects such as contamination and impact, and may provide structural rigidity to the semiconductor package 1. In order to perform this role, the package encapsulant 400 may include a thermosetting resin such as an epoxy resin. Specifically, the package encapsulant 400 may include Ajinomoto Buildup Film (ABF), Bismaleimide Triazine (BT), and/or the like. In addition, a molding material such as an epoxy mold compound (EMC) or a photosensitive material such as a photo imageable encapsulant (PIE) may be used as the package encapsulant 400. In addition, the package encapsulant 400 may be formed by processes such as compression molding, lamination, screen printing, etc.

Since the package encapsulant 400 surrounds the first semiconductor device 200 and the top surface of the first semiconductor device 200 and the top surface of the first encapsulant 410 have the same vertical level, or the first encapsulant 410 covers the top surface of the first semiconductor device 200, the first semiconductor device 220 may be protected from external environment and external impact. Therefore, the reliability of the semiconductor package 1 according to an embodiment may be improved.

Among the side surfaces of the first encapsulant 410, the first encapsulant outer surface 410S facing the outside of the semiconductor package 1 may form the same boundary as the substrate outer surface 110S that is the outer surface of the package substrate 110. Accordingly, the first encapsulant outer surface 410S may be vertically coplanar with the substrate outer surface 110S.

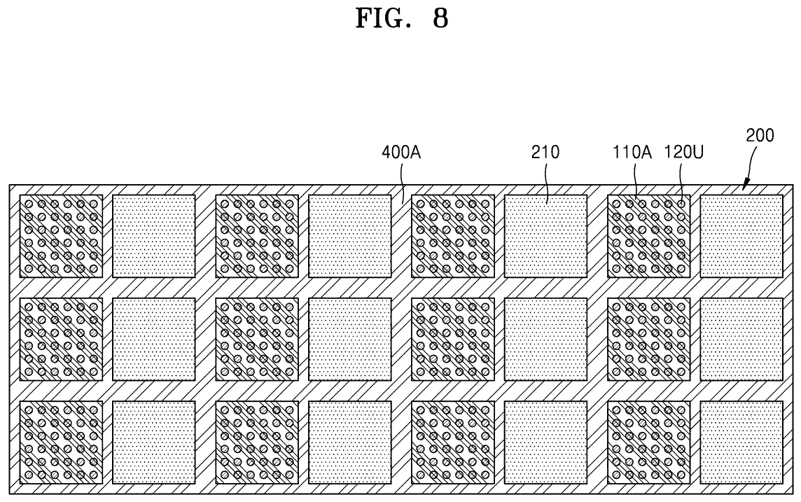

Similar to the case of the first encapsulant 410, the second encapsulant outer surface 420S facing the outside of the semiconductor package 1 among the side surfaces of the second encapsulant 420 may form the same boundary as the substrate outer surface 110S that is the outer surface of the package substrate 110. In other words, the second encapsulant outer surface 420S may be vertically coplanar with the substrate outer surface 110S. This is because the encapsulant 400A and the package substrate 110A (see FIG. 8) are simultaneously sawed (e.g., diced).

More particularly, one reason why the first encapsulant outer surface 410S and the second encapsulant outer surface 420S may be coplanar with the substrate outer side surface 110S is that the encapsulant 400A is sawed after being formed on the package substrate 110A. As will be described later, after a plurality of semiconductor devices are mounted on a plurality of package substrates 110A, respectively, and the encapsulant is formed, sawing work (i.e., dicing) is performed, and thus, a plurality of semiconductor packages 1 may be manufactured through a series of processes. Therefore, the productivity of fabricating the semiconductor package 1 according to an embodiment may be improved.

In the semiconductor package 1 according to an embodiment, the first semiconductor device 200 is provided on the package substrate 110A, and the package encapsulant 400A is formed, and then the package encapsulant 400A and the package substrate 110A (see FIG. 8) are sawed. In a typical semiconductor package manufacturing process, the package substrate is first sawed, and then the first semiconductor device is mounted and the package encapsulant of formed, on the package substrate. In contrast, the semiconductor package 1, according to an embodiment, forms the encapsulant 400A in advance before sawing on the package substrate 110A manufactured in a plane shape. In other words, an encapsulant 400A is first formed on the package substrate 110A before warpage is generated by sawing the package substrate 110A. Accordingly, the encapsulant 400A may prevent or reduce warpage due to sawing of the package substrate 110A. That is, the encapsulants 400 and 400A may perform a role similar to that of a stiffener. Therefore, the reliability of the semiconductor package 1 according to an embodiment may be improved.

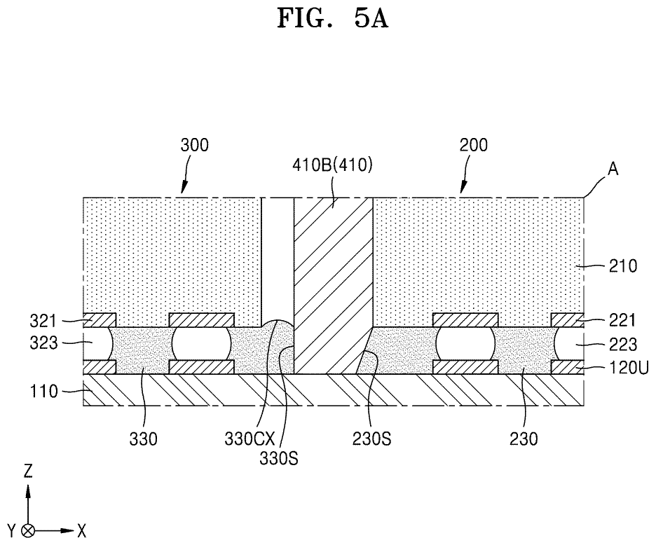

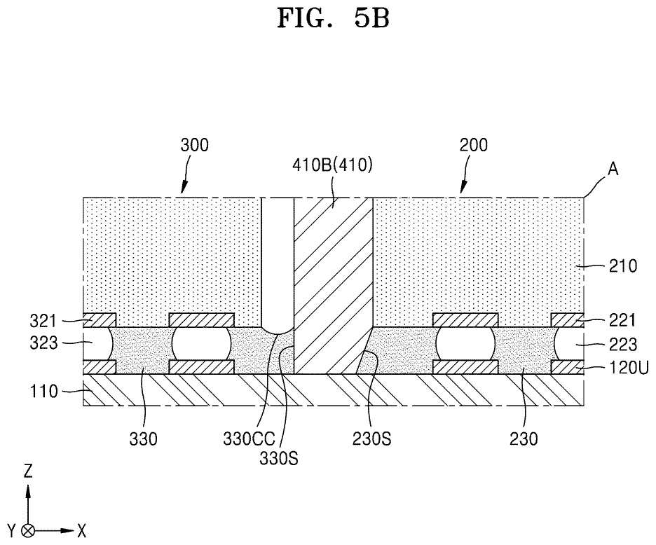

FIG. 3 is a plan view of an example semiconductor package 1A, according to an embodiment. FIG. 4 is a cross-sectional view illustrating the semiconductor package 1A of FIG. 3 according to an embodiment taken along line II-II′. FIG. 5A is an enlarged cross-sectional view of a portion A of the semiconductor package 1A shown in FIG. 3 according to an embodiment. FIG. 5B is an enlarged cross-sectional view of a portion A of the semiconductor package 1A shown in FIG. 3 according to another embodiment. Redundant descriptions of the same features as those described above will be omitted.

Referring to FIGS. 3, 4, 5A, and 5B, the semiconductor package 1A according to an embodiment may include a package substrate 110, a first semiconductor device 200 provided (e.g., mounted or otherwise attached) on the package substrate 110, a second semiconductor device 300 provided on the package substrate 110 laterally (i.e., horizontally) spaced apart from the first semiconductor device 200, and a package encapsulant 400 provided on the package substrate 110.

The second semiconductor device 300 may include a plurality of device connection pads 321 on a bottom surface thereof.

The second semiconductor device 300 may include, for example, an application processor (AP) such as a central processing unit (CPU), a graphic processing unit (GPU), a field-programmable gate array (FPGA), a digital signal processor, an encryption processor, a microprocessor, and/or a microcontroller. For example, the first semiconductor device 200 may be a logic chip such as an Analog-Digital Converter (ADC) or an application-specific IC (ASIC), or may include a memory chip such as a volatile memory (e.g., DRAM) or a nonvolatile memory (e.g., ROM or flash memory). A plurality of memory chips may be vertically stacked on one another (i.e., in the Z direction) and included in the second semiconductor device 300. For example, the second semiconductor device 300 may be a high bandwidth memory (HBM) or a wire bonding memory package in which a plurality of the memory chips are stacked on one another.

In some embodiments, the second semiconductor device 300 may be a semiconductor package. In the present specification, the second semiconductor device 300 may be referred to as a semiconductor package. Second connection terminals 323 may be provided between some (i.e., a first subset) of the upper connection pads 120U provided on the top surface of the package substrate 110 and the device connection pads 321 provided on the bottom surface of the second semiconductor device 300. Second connection terminals 323 may electrically connect the package substrate 110 with the second semiconductor device 300. For example, the second connection terminals 323 may be solder balls or microbumps, although embodiments are not limited thereto.

The semiconductor package 1A according to an embodiment may include a second underfill layer 330. The second underfill layer 330 may fill a space between the second semiconductor device 300 and the package substrate 110 and may surround (i.e., extend around) the second connection terminals 323. The second underfill layer 330 may include resin. For example, the second underfill layer 330 may be formed of an epoxy resin by a capillary underfill method. A filler may be mixed in the second underfill layer 330, and the filler may be formed of, for example, silica.

The second encapsulant 420 may extend around the second semiconductor device 300 and may be configured to be laterally spaced apart from the second semiconductor device 300. A first surface of the intermediate encapsulant 410B may be in contact with the side surface of the first semiconductor device 200. A second surface of the intermediate encapsulant 410B, which is opposite to the first surface of the intermediate encapsulant 410B, may face the side surface of the second semiconductor device 300. The second surface of the intermediate encapsulant 410B may be laterally spaced apart from the second semiconductor device 300, and the second surface of the intermediate encapsulant 410B may contact the side surface of the second underfill layer 330. Although ordinal terms such as “first” and “second” may be used herein to describe various elements or components in the present specification, these elements or components are not limited by these terms. These terms are merely used to distinguish a single element or component from other elements or components and should not be interpreted as conveying any particular order of the elements with respect to one another. Thus, a first element or component referred to herein may be termed a second element, and similarly a second element could be termed a first element, without departing from the scope of the present disclosure.

A fourth height H4, which is a vertical level between the top surface of the package substrate 110 and the bottom surface of the second semiconductor device 300, may be equal to or less than the second height H2, which is a vertical level between the top surface of the package substrate 110 and the top surface of the second encapsulant 420. This is to prevent overflowing in the process of placing the second underfill layer 330 between the top surface of the package substrate 110 and the second semiconductor device 300. The fourth height H4 may be substantially the same as the vertical thickness of the second underfill layer 320.

Referring to FIGS. 5A and 5B, at a portion where a side surface 330S of the second underfill layer 330 and the top surface of the package substrate 110 meet, the boundary of the side surface of the second underfill layer 330 and the top surface of the package substrate 110 may be perpendicular to each other. Alternatively, as described above, the boundary between the side surfaces 230S of the first underfill layer 230 and the top surface of the package substrate 110 may not be perpendicular to each other.

For example, a first underfill layer inclined side surface 230S contacting the first surface of the intermediate encapsulant 410B of the first underfill layer 230 may not be perpendicular to the top surface of the package substrate 110. A second underfill layer side surface 330S contacting the second surface of the intermediate encapsulant 410B, which is opposite to the first surface of the intermediate encapsulant 410B of the second underfill layer 330 may be perpendicular to the top surface of the package substrate 110. Therefore, the first surface of the intermediate encapsulant 410B in contact with the first underfill layer 230 may not be perpendicular to the package substrate 110, and the second surface of the intermediate encapsulant 410B in contact with the second underfill layer 330 may be perpendicular to the package substrate 110.

After the second semiconductor device 300 is provided on the package substrate 110, the second underfill layer 330 may be formed, for example, by a capillary underfill method through a space between the second encapsulant 420 and the second semiconductor device 300. The shape of the second underfill layer 330 between the second semiconductor device 300 and the second encapsulant 420 and between the second semiconductor device 300 and the intermediate encapsulant 410B may vary depending on the physical properties of the second underfill layer 330, supply amount, and the like.

For example, referring to FIG. 5A, the second underfill layer 330 may have a second underfill layer convex portion 330CX that is convex upward (in the Z direction) between the second semiconductor device 300 and the intermediate encapsulant 410B. Alternatively, referring to FIG. 5B, the second underfill layer 330 may have a second underfill layer concave portion 330CC that is concave downward (in the Z direction) between the second semiconductor device 300 and the intermediate encapsulant 410B.

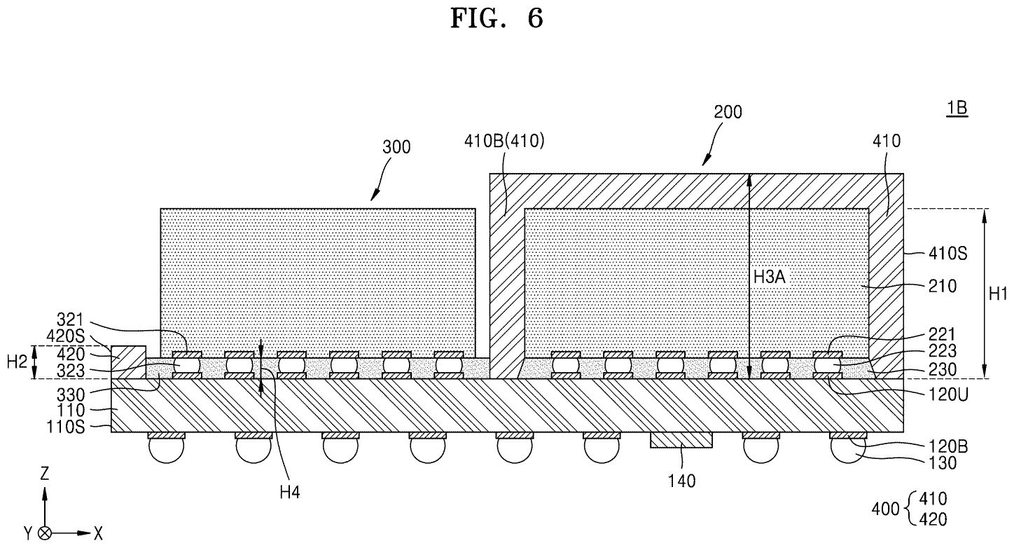

FIG. 6 is a cross-sectional view illustrating an example semiconductor package 1B according to an embodiment of the present disclosure.

Referring to FIG. 6, the first encapsulant 410 may cover a top surface of the first semiconductor device 200. The term “cover” (or “covering,” or like terms), as may be used herein, is intended to broadly refer to an element, structure or layer that is on or over another element, structure or layer, either directly or with one or more other intervening elements, structures or layers therebetween. The first height H1 may be less than the third height H3A, which is a vertical level of the top surface of the first semiconductor device 200 with respect to the top surface of the package substrate 110.

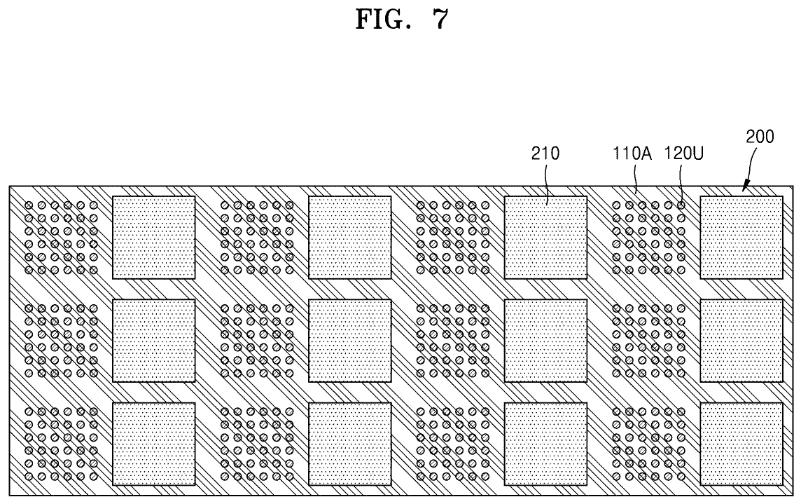

FIGS. 7 to 10 are plan view diagrams depicting intermediate processes in an example method of manufacturing a semiconductor package 1, according to an embodiment of the present disclosure. Redundant descriptions of the same features as those described above will be omitted.

Referring to FIG. 7, the plurality of upper connection pads 120U may be formed on the package substrate 110A, and the first semiconductor devices 200 may be provided (e.g., mounted or attached) on some of the plurality of upper connection pads 120U. The remaining ones of the plurality of upper connection pads 120U that are not connected to the first semiconductor device 200 may be maintained exposed. In FIG. 7, a package substrate 110A before sawing or dicing, which may be split into a total of 12 package substrates 110, is illustrated as an example, but the semiconductor package 1 according to an embodiment is not limited thereto.

Referring to FIG. 8, an encapsulant 400A may be formed on the process product of FIG. 7. The encapsulant 400A may be formed to surround (i.e., extend around) the side surface of the first semiconductor device 200, and at the same time, some of the upper connection pads 120U on which the second semiconductor devices 300 (see FIG. 6) may be provided may be exposed.

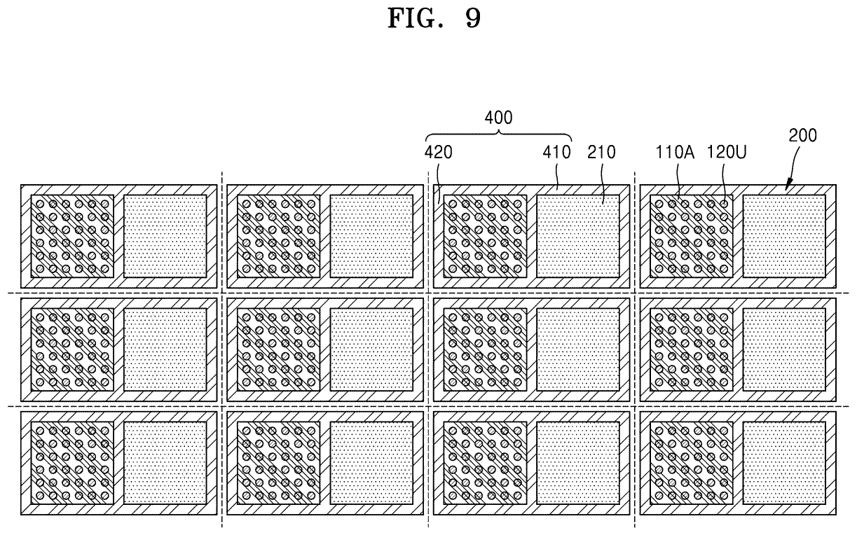

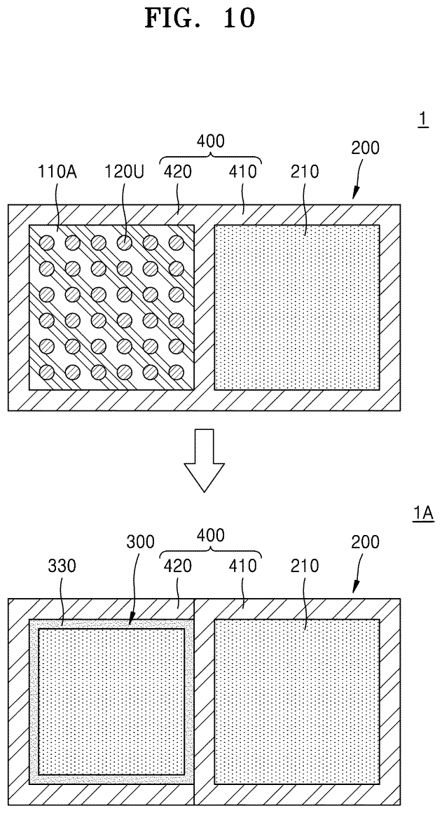

Referring to FIG. 9, the process product of FIG. 8 may be sawed (i.e., diced) to form a total of 12 individual (i.e., separated) semiconductor packages 1 (see FIG. 10). The encapsulant 400A in FIG. 8 is formed as the package encapsulant 400 for each package substrate 110 through sawing. As described above, after the encapsulant 400A is formed for the entire package substrate 110A, the package substrate 110A and the encapsulant 400A are sawed together. Accordingly, the shape of the outer edge of the package encapsulant 400 may be formed to be the same as the outer edge of the package substrate 110 after sawing.

Referring to FIG. 10, in the semiconductor package 1 according to an embodiment, the top surface of the package substrate 110 and the upper connection pad 120U on the top surface of the package substrate 110 may be exposed inside the second encapsulant 420. The second semiconductor device 300 is provided (e.g., mounted) on the exposed upper connection pad 120U, and the second underfill layer 330 is formed between the second semiconductor device 300 and the package substrate. Accordingly, a semiconductor package 1A according to an embodiment may be manufactured. The second underfill layer 330 may be exposed in a space between the second semiconductor device 300 and the second encapsulant 420 as shown in the lower drawing of FIG. 10 when the semiconductor package 1A is viewed from the top in a plan view.

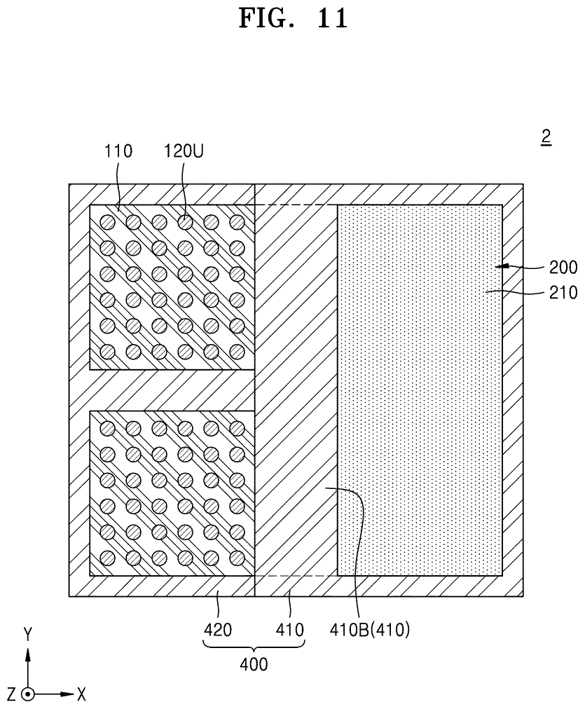

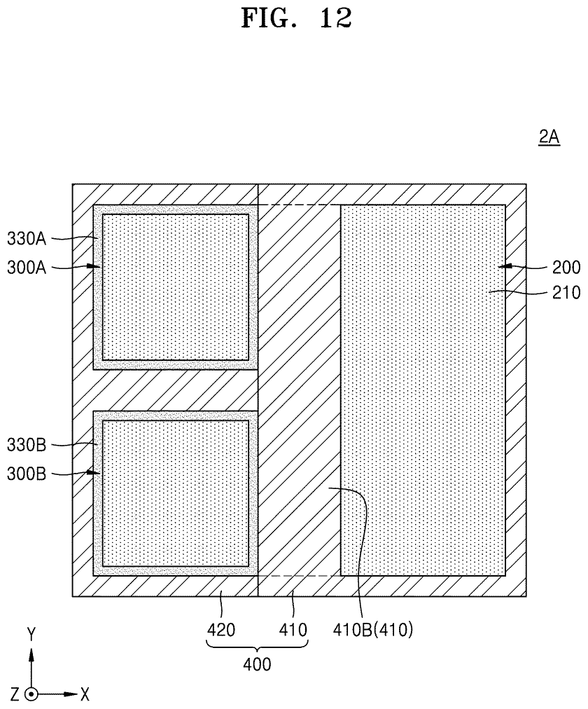

FIG. 11 is a plan view of a semiconductor package 2 according to an embodiment of the present disclosure. FIG. 12 is a plan view of a semiconductor package 2A according to another embodiment. Redundant descriptions of the same features as those described above will be omitted.

Referring to FIGS. 11 and 12, as shown in FIG. 12, a second encapsulant 420 may be formed on the package substrate 110 by emptying a space in which a second upper semiconductor device 300A and a second lower semiconductor device 300B are to be mounted. That is, the package encapsulant 400 may be provided in a shape in which the inside surfaces of the second encapsulant 420 is partially empty to expose the package substrate 110 and some of the upper connection pads 120U; that is, the inside surfaces of the second encapsulant 420 may define a space in which the top surface of the package substrate 110 and some of the upper connection pads 120U are exposed.

As shown in FIG. 12, the second upper semiconductor device 300A and the second lower semiconductor device 300B may be mounted at portions where the encapsulant is not formed inside the second encapsulant 420. Side surfaces of the second upper semiconductor device 300A and the second lower semiconductor device 300B may be laterally (i.e., in a horizontal plane) spaced apart from the inner side surface of the second encapsulant 420 and may not be in contact therewith. A second upper underfill layer 330A may be provided between the bottom surface of the second upper semiconductor device 300A and the top surface of the package substrate 110. Similarly, a second lower underfill layer 330B may be provided between the lower surface of the second lower semiconductor device 300B and the top surface of the package substrate 110. As illustrated in FIG. 12, when the semiconductor package 2A is viewed from the top in a plan view, the second upper underfill layer 330A may be exposed in a space between the second upper semiconductor device 300A and the second encapsulant 420. Likewise, the second lower underfill layer 330B may be exposed in a space between the second lower semiconductor device 300B and the second encapsulant 420.

The intermediate encapsulant 410B may be provided between the side surfaces of the second upper semiconductor device 300A and the second lower semiconductor device 300B facing the first semiconductor device 200 and the first semiconductor device 200. A first surface of the intermediate encapsulant 410B may be in contact with the first semiconductor device 200, and a second surface of the intermediate encapsulant 410B, which is opposite to the first surface of the intermediate encapsulant 410B, may face the second upper semiconductor device 300A and the second lower semiconductor device 300B, and may be laterally spaced apart therefrom.

The second encapsulant 420 laterally spaced apart from the second upper semiconductor device 300A and the second lower semiconductor device 300B may be provided between the second upper semiconductor device 300A and the second lower semiconductor device 300B. For example, some of the side surfaces of the second upper semiconductor device 300A may face the second encapsulant 420, and the other side surfaces of the second upper semiconductor device 300A may face the first encapsulant 410. Likewise, some of the side surfaces of the second lower semiconductor device 300B may face the second encapsulant 420, and the other side surfaces of the second lower semiconductor device 300B may face the first encapsulant 410.

In an embodiment, as shown in FIG. 12, three of the four side surfaces of the second upper semiconductor device 300A may face the inner surfaces of the second encapsulant 420 and be laterally spaced apart therefrom, and the remaining side surfaces of the second upper semiconductor device 300A may face one surface of the intermediate encapsulant 410B which is a part of the first encapsulant 410, and may be laterally spaced apart therefrom. Likewise, as shown in FIG. 12, three of the four side surfaces of the second lower semiconductor device 300B may face the inner surfaces of the second encapsulant 420 and may be laterally spaced apart therefrom, and the remaining side surfaces of the second lower semiconductor device 300B may face one surface of the intermediate encapsulant 410B, which is a part of the first encapsulant 410, and may be laterally spaced apart therefrom.

The second upper semiconductor device 300A and the second lower semiconductor device 300B may include an application processor (AP) such as a central processing unit (CPU), a graphic processing unit (GPU), a field-programmable gate array (FPGA), a digital signal processor, an encryption processor, a microprocessor, and a microcontroller. For example, the first semiconductor device 200 may be a logic chip such as an Analog-Digital Converter (ADC) or an application-specific IC (ASIC), or may include a memory chip such as a volatile memory (e.g., DRAM) or a nonvolatile memory (e.g., ROM or flash memory). A plurality of memory chips may be stacked on one another and included in the second semiconductor device 300. For example, the second semiconductor device 300 may be a high bandwidth memory (HBM) or a wire bonding memory package in which a plurality of the memory chips are stacked on one another.

While the inventive concept has been particularly shown and described with reference to embodiments thereof, it will be understood that various changes in form and details may be made therein without departing from the spirit and scope of the following claims.

What is claimed is:

1. A semiconductor package, comprising:
a package substrate;
a first semiconductor device on the package substrate;
a second semiconductor device on the package substrate and spaced laterally from the first semiconductor device; and
a package encapsulant including a first encapsulant and a second encapsulant, wherein the first encapsulant is on the package substrate, in contact with side surfaces of the first semiconductor device and at least partially encloses the side surfaces of the first semiconductor device, and the second encapsulant is on the package substrate and laterally spaced apart from some side surfaces of the second semiconductor device, wherein
the first encapsulant and the second encapsulant are integrally provided, and some side surfaces of the package encapsulant are coplanar with an outer edge of the package substrate.

2. The semiconductor package of claim 1, wherein a first height, which is a vertical level of the first encapsulant relative to a top surface of the package substrate, is greater than a second height, which is a vertical level of the second encapsulant relative to the top surface of the package substrate.

3. The semiconductor package of claim 2, wherein the second height is less than or equal to half the first height.

4. The semiconductor package of claim 2, wherein the first height is equal to or greater than a third height, which is a vertical level of a top surface of the first semiconductor device relative to the top surface of the package substrate.

5. The semiconductor package of claim 4, wherein the second height is equal to or greater than a fourth height, which is a vertical level of a bottom surface of the second semiconductor device relative to the top surface of the package substrate.

6. The semiconductor package of claim 1, wherein the first encapsulant extends around side surfaces of the first semiconductor device and a top surface of the first semiconductor device.

7. The semiconductor package of claim 2, further comprising: a first underfill layer between the first semiconductor device and the package substrate; and a second underfill layer between the second semiconductor device and the package substrate.

8. The semiconductor package of claim 7, wherein a thickness of the second underfill layer, which is a distance between a top surface of the second underfill layer in contact with the second semiconductor device and a bottom surface of the second underfill layer in contact with the package substrate, is smaller than the second height.

9. The semiconductor package of claim 1, wherein the second encapsulant faces at least one side surface of the second semiconductor device.

10. The semiconductor package of claim 8, wherein at least a subset of side surfaces of the second underfill layer is in contact with the second encapsulant.

11. The semiconductor package of claim 10, wherein a shape in which a top surface of the second underfill layer at least partially overlaps the package substrate is the same as a shape of a bottom surface of the second underfill layer when viewed in plan view, the bottom surface of the second underfill layer being in contact with the package substrate.

12. The semiconductor package of claim 10, wherein the side surfaces of the second underfill layer are perpendicular to the top surface of the package substrate.

13. The semiconductor package of claim 10, wherein a cross-sectional shape of the first underfill layer is a tapered shape in which a horizontal width of the first underfill layer decreases with increasing vertical distance from the package substrate.

14. The semiconductor package of claim 11, wherein the second underfill layer includes a convex underfill portion that is convex upward, relative to the top surface of the package substrate, or a concave underfill portion that is concave downward, relative to the top surface of the package substrate, in a space between the first encapsulant and the second semiconductor device or between the second encapsulant and the second semiconductor device.

15. The semiconductor package of claim 1, wherein the first semiconductor device includes an application processor, and the second semiconductor device includes at least one memory chip.

16. A semiconductor package, comprising:
a package substrate having a plurality of upper connection pads on a top surface thereof;
a first semiconductor device on the package substrate and electrically connected to a first subset of the plurality of upper connection pads; and
a package encapsulant including a first encapsulant and a second encapsulant, wherein the first encapsulant is on the package substrate and is in contact with at least some side surfaces of the first semiconductor device at a perimeter of the first semiconductor device, and the second encapsulant is on the package substrate and laterally spaced from a second subset of the plurality of upper connection pads, and at least partially encloses the second subset of the plurality of upper connection pads, wherein
the first encapsulant and the second encapsulant are integrally provided, and
a first height, which is a vertical level of the first encapsulant relative to the top surface of the package substrate, is greater than a second height, which is a vertical level of the second encapsulant relative to the top surface of the package substrate,
the first height is equal to or greater than a third height, which is a vertical level of a top surface of the first semiconductor device relative to the top surface of the package substrate, and
some side surfaces of the package encapsulant are coplanar with an outer edge of the package substrate.

17. The semiconductor package of claim 16, wherein the first semiconductor device includes an application processor.

18. The semiconductor package of claim 16, wherein a top surface of the first encapsulant and the top surface of the first semiconductor device are coplanar.

19. A semiconductor package, comprising:
a package substrate having a plurality of upper connection pads on a top surface thereof;
a first semiconductor device on the package substrate and electrically connected to a first subset of the plurality of upper connection pads; and
a package encapsulant including a first encapsulant and a second encapsulant, wherein the first encapsulant is on the package substrate and in contact with at least some side surfaces of the first semiconductor device at a perimeter of the first semiconductor device, and the second encapsulant is on the package substrate and laterally spaced from a second subset of the plurality of upper connection pads, and at least partially encloses the second subset of the plurality of upper connection pads, wherein
the first encapsulant and the second encapsulant are integrally provided, and
a first height, which is a vertical level of the first encapsulant relative to the top surface of the package substrate, is greater than a second height, which is a vertical level of the second encapsulant relative to the top surface of the package substrate, the second height is less than or equal to half the first height,
the first height is equal to or greater than a third height, which is a vertical level of a top surface of the first semiconductor device relative to the top surface of the package substrate, and
some side surfaces of the package encapsulant are coplanar with an outer edge of the package substrate.

20. The semiconductor package of claim 19, further comprising
a first underfill layer between the first semiconductor device and the package substrate, wherein
a thickness of the first underfill layer, which is a vertical distance between a top surface of the first underfill layer in contact with the first semiconductor device and a bottom surface of the first underfill layer in contact with the top surface of the package substrate, is smaller than the second height, and
a cross-sectional shape of the first underfill layer is a tapered shape in which a horizontal width of the first underfill layer decreases with increasing distance from the package substrate.
